(19) United States
(12) Patent Application Publication
(10) Pub. No.: US 2012/0198290 A1
(43) Pub. Date: Aug. 2, 2012

(54) NON-VOLATILE MEMORY DEVICE AND PROGRAMMING METHOD THEREOF

(76) Inventors: Myung CHO, Gyeonggi-do (KR); Ji-Hwan KIM, Gyeonggi-do (KR)

(21) Appl. No.: 13/116,978

(22) Filed: May 26, 2011

(30) Foreign Application Priority Data
Jan. 28, 2011 (KR) 10-2011-0008789

(51) Int. Cl. G11C 29/08; G06F 11/07

(52) U.S. Cl. 714/708; 714/718; 714/704; 714/E11.024

(57) ABSTRACT

A method for performing a program operation in a non-volatile memory device includes applying a programming pulse to a plurality of memory cells, verifying whether the plurality of the memory cells are programmed to produce a verification result, determining whether all of the plurality of the memory cells are programmed in response to the verification result to produce a first determination result and determining whether at least a first number of memory cells are programmed among the plurality of the memory cells in response to the first determination result to produce a second determination result.

### CROSS-REFERENCE TO RELATED APPLICATIONS

The present application claims priority of Korean Patent Application No. 10-2011-0008789, filed on Jan. 28, 2011, which is incorporated herein by reference in its entirety.

### BACKGROUND

1. Field

Exemplary embodiments of the present invention relate to a semiconductor designing technology, and more particularly, to a non-volatile memory device and a method for performing a program operation in the non-volatile memory device.

2. Description of the Related Art

In general, semiconductor memory devices may be classified into volatile memory devices, such as Dynamic Random Access Memory (DRAM) devices and Static Random Access Memory (SRAM) devices, and non-volatile memory devices, such as Programmable Read Only Memory (PROM) devices, Erasable PROM (EPROM) devices, Electrically EPROM (EEPROM) devices, and flash memory devices. Non-volatile memory devices are mainly distinguished from volatile memory devices based on whether stored data are retained or not after a predetermined time passes. More specifically, volatile memory devices may not retain the data stored in a memory cell after a predetermined time passes, whereas non-volatile memory devices retain the data stored in a memory cell after a predetermined time passes. Therefore, volatile memory devices necessarily perform a refresh operation to keep the data, while non-volatile memory devices do not perform a refresh operation. Since such non-volatile memory devices are appropriate for low power consumption and high integration, they are widely used as storages for portable devices.

Meanwhile, flash memory devices of the non-volatile memory devices perform a program operation and an erase operation to store data in memory cells. Here, the program operation is an operation for accumulating electrons in a floating gate of a transistor which constitutes a memory cell, and the erase operation is an operation for discharging electrons accumulated in a floating gate into a substrate. A flash memory device stores a data of ‘0’ or ‘1’ in a memory cell through the program operation and the erase operation. During a read operation, the flash memory device senses the amount of electrons accumulated in a floating gate and determines the stored data (i.e., ‘0’ or ‘1’) based on the sensing result.

As illustrated in the above, one memory cell stores a data of ‘0’ or ‘1’. In short, one-bit data is stored in one memory cell, and this kind of a memory cell is referred to as a single-level cell. A scheme of storing more than one-bit data in one memory cell is being applied to a flash memory device, and this kind of a memory cell is referred to as a multi-level cell.

FIG. 1 is a flowchart describing a program operation of a conventional flash memory device.

Referring to FIG. 1, a program operation of a conventional flash memory device includes: adjusting a programming pulse and applying the adjusted programming pulse in step S120, verifying the programming in step S130, determining whether all data are programmed in step S140, determining whether the programming pulse is applied a set number of times in step S150, detecting the number of error bits in step S160, and determining whether the number of error bits is smaller than the number of correctable bits in step S170. Here, the step S160 is generally performed in a current sensing circuit (CSC), an operation of which is slow and consumes significant current.

The program operation may further include a start step S110 and an end step S180 as shown in FIG. 1. Hereafter, the program operation is described briefly.

First, in step S120 after the start step of S110, a programming pulse of a predetermined voltage level is applied to a plurality of memory cells. An Incremental Step Pulse Program (ISPP) may be used for threshold voltages of memory cells to have a desired distribution. Here, the ISPP is a method of programming memory cells by using a pulse, where the pulse has an amplitude (i.e., a voltage) that increases step by step (incrementally) from an initial voltage. Subsequently, in step S130, whether the multiple memory cells are programmed or not is verified. In step S140, a determination is made as to whether all the data are properly programmed in the memory cells or not. If it is determined in step S140 that all the data are properly programmed in the memory cells (yes), the program operation is terminated in step S180. Otherwise (no), the process of step S150 is performed.

In step S150, it is determined whether the programming pulse has been applied for a set number of times (that is, for a number of times that is equal to or exceeds the set number of times). If it is determined in step S150 that the programming pulse has been applied for the set number of times (yes), the process of step S160 is performed. Otherwise (no), the process of step S120 is performed. Returning to step S120, the programming pulse of the predetermined voltage level is adjusted, and the adjusted programming pulse is applied to the memory cells.

Meanwhile, in step S160, the number of error bits is detected. Subsequently, it is decided whether the number of the error bits is smaller than the number of correctable bits. If it is determined in step S160 that the number of the error bits is smaller than the number of correctable bits (yes), the program operation is terminated in step S180. Otherwise (no), the process of step S120 is performed. Here, the process of step S180 may be followed by a process of correcting the error bits, and the program operation is performed through the above-described series of operations.

Meanwhile, the conventional program operation has the following features that may degrade performance.

First, it may be a concern that the starting time point of the step S160 in which the number of error bits is detected.

As shown in the flowchart of FIG. 1, in step S150, a determination is made as to whether the programming pulse is applied for the set number of times, and then the operation of step S160 begins when the programming pulse is applied for the set number of times. This signifies that the starting time point of the operation of step S160 is fixed all the time after the set number of times for the programming pulse being applied. In other words, although the number of the error bits may fall within a correctable range in step S150, if the programming pulse is not applied for the set number of times, the process of step S160 is not performed and the process goes back to step S120. Here, the program operation may unnecessarily consume a long period time.

Second, the operation time of step S160 in which the number of error bits is detected may be a concern.

After the process of step S150 where a determination as to whether the programming pulse is applied for the set number of times is made, the number of error bits may be greater than the number of correctable bits, or conversely, the number of error bits may be smaller than the number of correctable bits. Here, the operation time of the process of step S160 may become long when the number of detected error bits is great. Subsequently, when the number of error bits is greater than the number of correctable bits in the step S170, the process of step S120 is performed. Therefore, the operation of detecting the number of error bits in step S160 takes time and adds to the entire time for the program operation.

### SUMMARY

An embodiment of the present invention is directed to a non-volatile memory device that may perform a program operation efficiently, and a program operation method thereof.

In accordance with an embodiment of the present invention, a method for performing a program operation in a non-volatile memory device includes: applying a programming pulse to a plurality of memory cells; verifying whether the plurality of the memory cells are programmed to produce a verification result; determining whether all of the plurality of the memory cells are programmed in response to the verification result to produce a first determination result; and determining whether at least a first number of memory cells are programmed among the plurality of the memory cells in response to the first determination result to produce a second determination result.

In accordance with another embodiment of the present invention, a method for performing a program operation in a non-volatile memory device includes: applying a programming pulse to a plurality of memory cells; checking whether the plurality of the memory cells are programmed and outputting a verification signal as a check result; determining a number of programmed memory cells among the plurality of the memory cells in response to the verification signal to produce a determination result; and terminating the program operation in response to the determination result.

In accordance with yet another embodiment of the present invention, a non-volatile memory device includes: a page buffer configured to generate a verification result signal in response to a result of programming a plurality of memory cells; and a result comparator configured to generate a program termination signal by comparing the verification result signal with a reference signal corresponding to a target number of memory cells to be programmed among the plurality of the memory cells.

The non-volatile memory device in accordance with an embodiment of the present invention may optimize the operation time point of a process of detecting the number of error bits by determining the extent that a program operation has been performed. Also, the non-volatile memory device may minimize the operation time of the process of detecting the number of error bits.

### BRIEF DESCRIPTION OF THE DRAWINGS

FIG. 1 is a flowchart describing a program operation of a conventional flash memory device.

FIG. 2 is a flowchart describing a program operation of a flash memory device in accordance with a first embodiment of the present invention.

FIG. 3 is a circuit diagram illustrating a circuit related to a process of determining whether all memory cells are programmed or not in step S240 of FIG. 2.

FIG. 4 is a circuit diagram illustrating a circuit for determining whether a program operation is performed up to a predetermined extent or not in step S250 of FIG. 2.

FIG. 5 is an operation timing diagram schematically illustrating the operations of circuits of FIGS. 3 and 4.

FIG. 6 is a flowchart describing a program operation of a flash memory device in accordance with a second embodiment of the present invention.

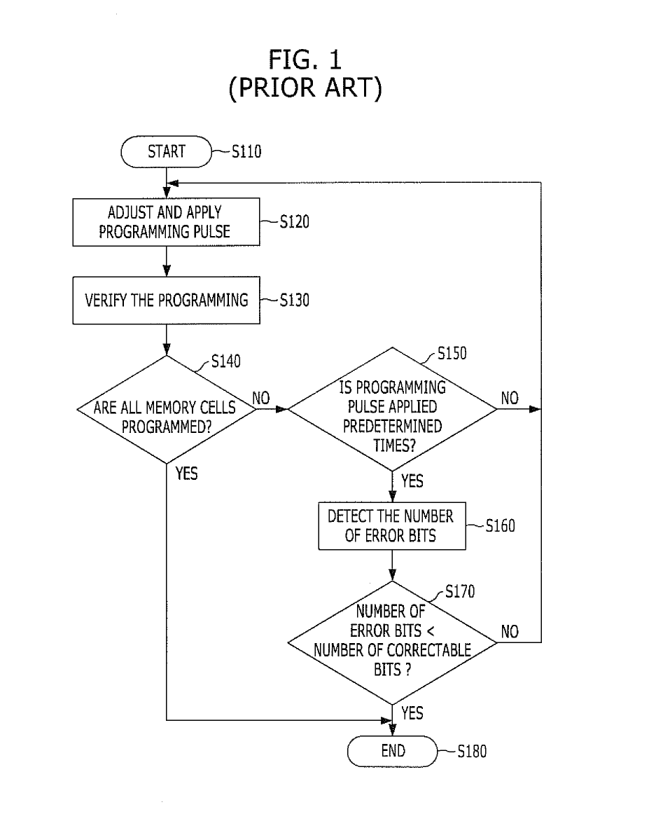

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

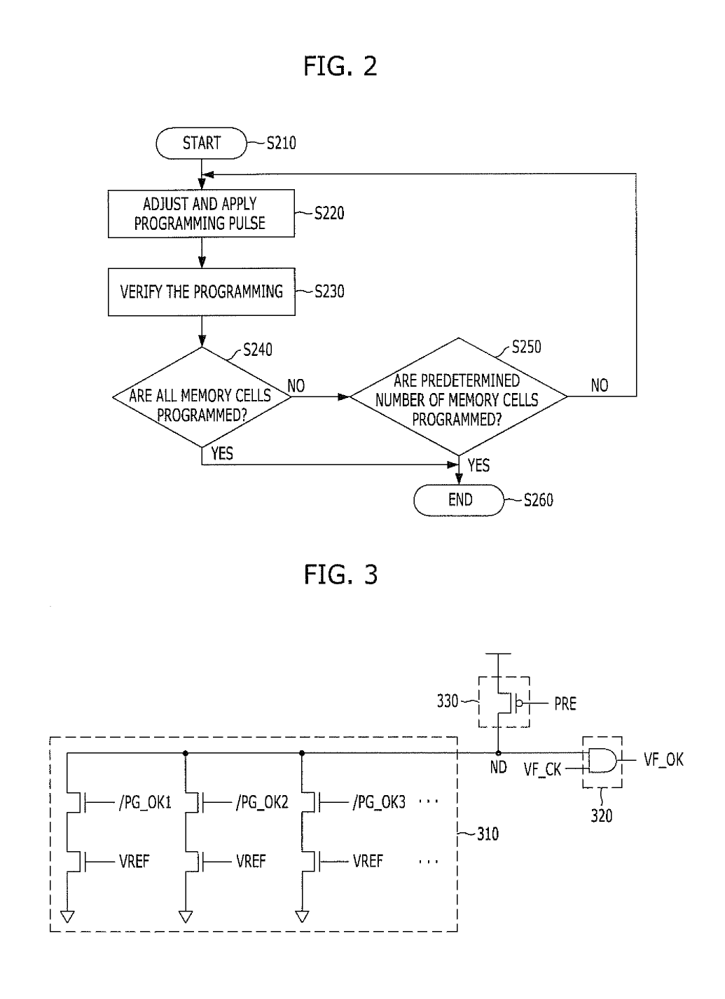

FIG. 2 is a flowchart describing a program operation of a flash memory device in accordance with a first embodiment of the present invention.

Referring to FIG. 2, the program operation of a flash memory device includes adjusting a programming pulse and applying the adjusted programming pulse in step S220, verifying the programming in step S230, determining whether all data are properly programmed in step S240, and determining whether the program operation is performed up to a predetermined extent in step S250,

The program operation may further include a start step S210 and an end step S260 as shown FIG. 2. Hereafter, the program operation is described briefly.

First, in step S220 after the start step of S210, a programming pulse of a predetermined voltage level is applied to a plurality of memory cells. Subsequently, in step S230, whether the multiple memory cells are programmed or not is verified. In step S240, it is determined whether all the data are properly programmed in the memory cells or not. If it is determined in step S240 that all the data are properly programmed in the memory cells (yes), the program operation is terminated in step S260. Otherwise (no), the process of step S250 is performed.

In step S250, it is determined whether a set number of the memory cells are programmed. If it is determined in step S250 that the predetermined/set number of memory cells are programmed (yes), the program process is terminated in step S260. Otherwise (no), the logic flow goes back to step S220 and the programming pulse of the predetermined voltage level is adjusted and the adjusted programming pulse is applied to the memory cells in step S220. The process of step S260 may be followed by a process of correcting error bits, and the program operation is performed through the series of process described in the above.

According to the program operation of the flash memory device in accordance with the first embodiment of the present invention, the extent of the program operation performed on the memory cells is determined in step S250. When it is determined that the program operation is performed up to a predetermined extent, the program operation is terminated. Here, the predetermined extent may be set to be different for different environments in which the exemplary embodiments of the present invention are used, and it may be set based on the number of error bits that may be corrected after the process of step S260.

FIG. 3 is a circuit diagram illustrating a circuit related to the process of step S240 where it is determined whether all memory cells are programmed or not in the flash memory device of FIG. 2. The drawing shows a page buffer corresponding to a plurality of memory cells.

Referring to FIG. 3, the page buffer includes a confirmation signal input unit 310, a verification signal output unit 320, and a pre-charging unit 330 to detecting how many of the multiple memory cells are programmed.

The confirmation signal input unit 310 discharges charges pre-charged in a common node ND in response to the programming confirmation signal /PG_OK1, /PG_OK2, /PG_OK3 . . . which corresponds to each of the memory cells. The confirmation signal input unit 310 includes a plurality of NMOS transistors for receiving the programming confirmation signal /PG_OK1, /PG_OK2, /PG_OK3 . . . through a gate and a plurality of NMOS transistors for receiving a reference bias voltage VREF through a gate. Here, the programming confirmation signal /PG_OK1, /PG_OK2, /PG_OK3 . . . has a logic level corresponding to whether a corresponding memory cell is programmed or not. In other words, when a corresponding memory cell is programmed with a desired data, the corresponding programming confirmation signal may be in a logic low level. When a corresponding memory cell is not programmed with a data yet, the corresponding programming confirmation signal may be in a logic high level.

The verification signal output unit 320 outputs a verification result signal VF_OK corresponding to the voltage level of the common node ND in response to a verification check signal VF_CK. The verification signal output unit 320 includes an AND gate which receives a signal of the common node ND and the verification check signal VF_CK, and outputs the verification result signal VF_OK. Here, the verification check signal VF_CK is a pulse signal enabled in a programming check operation of step S230.

Lastly, the pre-charging unit 330 charges the common node ND to have a predetermined voltage level before the programming check operation of step S240. The pre-charging unit 330 includes a PMOS transistor for charging the common node ND to have a predetermined voltage level in response to a pre-charge signal PRE. Therefore, the common node ND is charged to the predetermined voltage level in response to a pre-charge signal PRE which is enabled before the verification check signal VF_CK is enabled.

Hereafter, a simple circuit operation of the page buffer is described. For the sake of convenience in description, it is assumed that a corresponding NMOS transistor is turned on based on the reference bias voltage VREF.

First, the common node ND is pre-charged to the predetermined voltage level in response to the pre-charge signal PRE. Subsequently, as described in the above, the logic level of the programming confirmation signal /PG_OK1, /PG_OK2, /PG_OK3 . . . becomes a logic low when the corresponding memory cell is programmed with a desired data, otherwise, the logic level of the programming confirmation signal becomes a logic high. In other words, when there are many memory cells that are not programmed yet, the common node ND pre-charged with charges are discharged rapidly, and conversely, when there are many memory cells that are programmed, the common node ND maintains the pre-charged level as much. Therefore, in a state where the verification check signal VF_CK is enabled to a logic high level, the verification result signal VF_OK becomes a pulse signal having a logic high pulse width that varies in response to, for example, the number of programmed memory cells and may indicate whether all memory cells have been programmed by a corresponding pulse width.

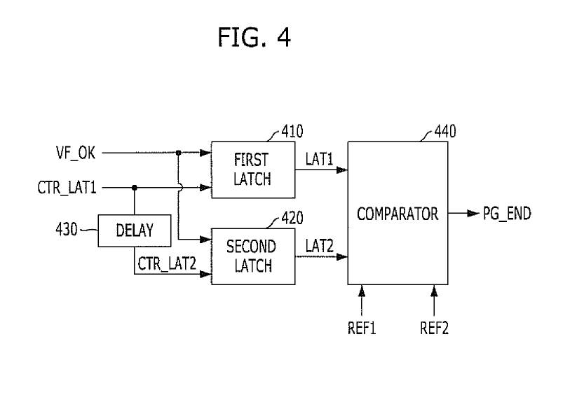

FIG. 4 is a circuit diagram illustrating a circuit related to the process of step S250 which determines whether a program operation is performed up to a predetermined extent or not in the flash memory device of FIG. 2. According to an example, the FIG. 4 circuit may also be used to determine whether all memory cells have been programmed in step S240. The drawing shows a result comparison unit for receiving the output signal of the page buffer shown in FIG. 3, which is the verification result signal VF_OK.

Referring to FIG. 4, the result comparison unit compares corresponding first and second reference signals REF1 and REF2 with the verification result signal VF_OK and generates a programming termination signal PG_END when a set number of memory cells are programmed. The result comparison unit includes a first latch 410, a second latch 420, a delay 430, and a comparator 440.

The first latch 410 latches the verification result signal VF_OK in response to a first latch control signal CTL_LAT1 and outputs a first level latch signal LAT1. The second latch 420 latches the verification result signal VF_OK in response to a second latch control signal CTL_LAT2 and outputs a second level latch signal LAT2. Here, the delay 430 delays the first latch control signal CTL_LAT1 by a predetermined time and outputs the second latch control signal CTL_LAT2.

The result comparison unit of FIG. 4 includes the first latch 410 and the second latch 420 which respond to the first latch control signal CTL_LAT1 and the second latch control signal CTL_LAT2, but the structure may be modified according to different design needs. For example, the result comparison unit may include one latch which makes a response to one latch control signal, or it may be designed to include more than two latches which respond to more than two latch control signals. When the result comparison unit includes many latches, the accuracy of a detection result increases because the number of level latch signals is increased as the number of the latches increases.

The comparator 440 compares the first and second level latch signals LAT1 and LAT2 with the first and second reference signals REF1 and REF2 and outputs the programming termination signal PG_END. The programming termination signal PG_END may have a logic level corresponding to the comparison result between the first and second level latch signals LAT1 and LAT2 and the first and second reference signals REF1 and REF2, which will be described later again.

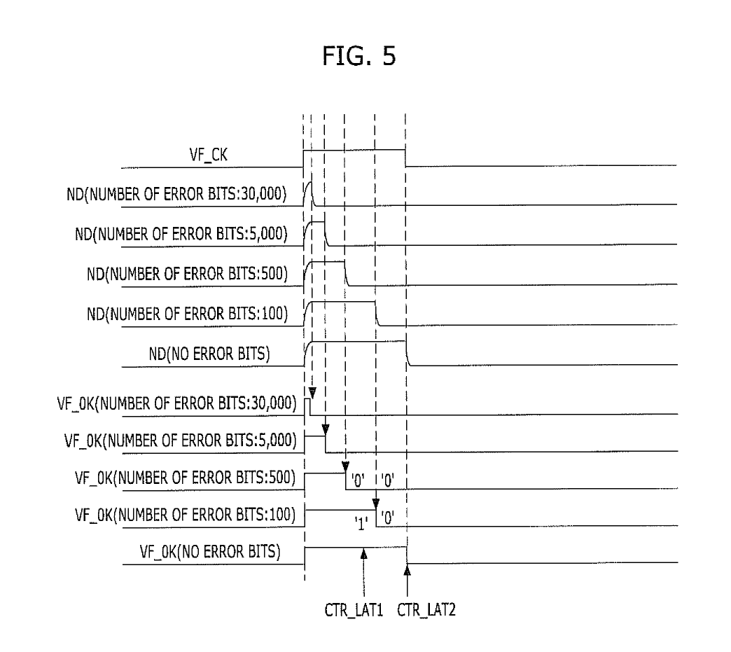

FIG. 5 is an operation timing diagram schematically illustrating the operations of circuits of FIGS. 3 and 4.

As already described with reference to FIG. 3, the pulse width of the verification result signal VF_OK becomes narrower as the number of error bits is larger, and its pulse width becomes wider as the number of error bits is smaller. FIG. 5 shows a case where the number of error bits is approximately 30,000; a case where the number of error bits is approximately 5,000; a case where the number of error bits is approximately 500; a case where the number of error bits is approximately 100; and a case where there is no error bit. The case where there is no error bit may be detected by the FIG. 4 circuit to perform the determination of whether all memory cells have been programmed in step S240.

Meanwhile, the first latch control signal CTL_LAT1 and the second latch control signal CTL_LAT2 are enabled sequentially, and the first latch 410 and the second latch 420 latch the verification result signal VF_OK of a corresponding time point. As illustrated in the drawing, when there are approximately 500 error bits, the first and second level latch signals LAT1 and LAT2 are all in logic low level by latching the verification result signal VF_OK of a logic low level in response to the first and second latch control signals CTL_LAT1 and CTL_LAT2. When there are approximately 100 error bits, the first level latch signal LAT1 is in logic high level and the second level latch signal LAT2 is in logic low level by latching the verification result signal VF_OK of a logic high level and a logic low level, respectively. Therefore, the first and second level latch signals LAT1 and LAT2 become ‘00’ when the number of error bits is approximately 500 (inclusive of 5,000 and 30,000), and the first and second level latch signals LAT1 and LAT2 become ‘10’ when the number of error bits is approximately 100.

Subsequently, the comparator 440 compares the first and second level latch signals LAT1 and LAT2 with the first and second reference signals REF1 and REF2 and outputs the programming termination signal PG_END. For example, the logic level of the programming termination signal PG_END becomes a logic high level when the first and second level latch signals LAT1 and LAT2 are the same as the first and second reference signals REF1 and REF2. When they are different, the logic level of the programming termination signal PG_END becomes a logic low level. Here, the programming termination signal PG_END being in a logic high level represents a case of ‘yes’ in step S250 of FIG. 2, and the programming termination signal PG_END being in a logic low level represents a case of ‘no’.

For example, when the first and second reference signals REF1 and REF2 are set to ‘10’, it means that approximately 100 error bits may be corrected in the process of correcting error bits, which is performed after the end step S260 is performed. At this time, if the programming termination signal PG_END is in a logic high level, it means that the approximately 100 error bits has occurred so far. Therefore, although the program operation is terminated, all occurring error bits may be corrected sufficiently.

The flash memory device in accordance with the embodiment of the present invention, as illustrated in FIG. 5, may decide when the program operation is terminated by detecting the pulse width of the verification result signal VF_OK. In particular, in the embodiment, the time point when the verification result signal VF_OK transitions from a logic high level to a logic low level is detected, and the termination time point of the program operation is decided based on the detected time point when the verification result signal VF_OK transitions from a logic high level to a logic low level.

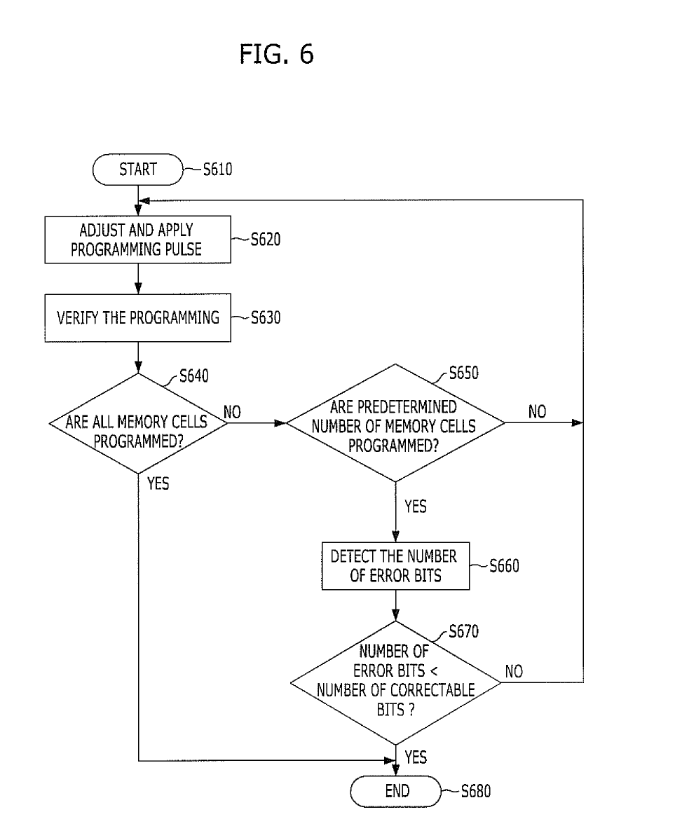

FIG. 6 is a flowchart describing a program operation of a flash memory device in accordance with a second embodiment of the present invention.

Referring to FIG. 6, the program operation of the flash memory device includes applying a programming pulse of a predetermined voltage level to a plurality of memory cells in step S620, verifying whether the memory cells are programmed or not in step S630, and determining whether all of the memory cells are properly programmed with data in step S640. If it is determined in step S640 that all of the memory cells are properly programmed with data (yes), the program operation is terminated in step S680. Otherwise (no), the process of step S650 is performed.

It is determined in step S650 whether a set number of the memory cells are programmed. If it is determined in step S650 that the set number of memory cells are programmed (yes), the process of step S660 is performed. Otherwise (no), the process of step S620 is performed. Getting back to step S620, the programming pulse of the predetermined voltage level is adjusted, and the adjusted programming pulse is applied to a corresponding memory cell.

Meanwhile, in step S660, the number of error bits is detected, and it is determined in step S670 whether the number of error bits is smaller than the number of correctable bits. If it is determined in step S670 that the number of error bits is smaller than the number of correctable bits (yes), the program operation is terminated in step S680. Otherwise (no), the process of step S620 is performed. Here, the step S680 is followed by a process of correcting error bits, and the program operation is performed through the above-described series of processes.

The second embodiment of the present invention provides an example where a Current Sensing Circuit (CSC) is provided and, hereafter, features of the program operation according to the embodiment of the present invention are described.

First, the starting time point of the process of step S660 in which the number of error bits is detected is described.

As shown in the flowchart of FIG. 6, the starting time point of the process of step S660 is decided based on the result of the process step S650 where it is determined whether the multiple memory cells are programmed up to the predetermined extent. In other words, the starting time point of the process of step S660 is variable. To be specific, the starting time point of the process of step S660 varies based on the number of programmed memory cells among the multiple memory cells. Ultimately, the process of step S660 is performed when the number of error bits falls within the correctable range and this signifies that the process of step S660 is performed at the optimal time point.

Second, the operation time of the process of step S660 where the number of error bits is detected is described.

When the process of step S660 is decided to be performed as a result of the process of step S650, the number of error bits is less than a set number. This means that when the number of the error bits is detected in the process of step S660, the operation time of the process of step S660 is minimized.

The program operation of the non-volatile memory device in accordance with the second embodiment of the present invention may shorten the time taken for the program operation and minimize current consumption during a CSC operation by optimizing the starting time point of the process of step S660 and minimizing the operation time of the process of step S660.

While the present invention has been described with respect to the specific embodiments, it will be apparent to those skilled in the art that various changes and modifications may be made without departing from the spirit and scope of the invention as defined in the following claims.

Moreover, the logic gates and transistors exemplified in the above-described embodiments are realized differently in their position and kind according to the polarity of an input signal.

What is claimed is:

1. A method for performing a program operation in a non-volatile memory device, comprising:
applying a programming pulse to a plurality of memory cells;
verifying whether the plurality of the memory cells are programmed to produce a verification result;
determining whether all of the plurality of the memory cells are programmed in response to the verification result to produce a first determination result; and
determining whether at least a first number of memory cells are programmed among the plurality of the memory cells in response to the first determination result to produce a second determination result.

2. The method of claim 1, wherein the determining of whether at least the first number of memory cells are programmed among the plurality of the memory cells is performed in response to the first determination result that less than all of the plurality of the memory cells are programmed.

3. The method of claim 1, further comprising:
increasing a voltage level of the programming pulse in response to the second determination result that less than the first number of memory cells are programmed, and
terminating the program operation in response to the second determination result that at least the first number of memory cells are programmed.

4. The method of claim 1, wherein a pulse signal having a pulse width that varies in response to a variation in a number of programmed memory cells among the plurality of the memory cells is outputted as the first determination result.

5. The method of claim 4, wherein, in the determining of whether at least the first number of memory cells are programmed,
the pulse width of the pulse signal is detected.

6. The method of claim 4, wherein, in the determining of whether at least the first number of memory cells are programmed,
a detection as to whether the pulse signal transitions between first and second time points is made.

7. The method of claim 4, wherein the determining of whether at least the first number of memory cells are programmed comprises:
detecting a level of the pulse signal in response to a first time point;
detecting the level of the pulse signal in response to a second time point after the first time point; and
comparing a result of detecting the level of the pulse signal and a result of detecting the level of the pulse signal with a reference signal corresponding to the target number.

8. The method of claim 1, further comprising:
detecting a number of error bits of the plurality of the memory cells after the determining of whether the first number of memory cells are programmed.

9. The method of claim 8, further comprising:
determining whether the number of error bits is smaller than a number of correctable bits of the plurality of the memory cells.

10. The method of claim 9, further comprising:
increasing a voltage level of the programming pulse when the number of error bits is greater than the number of correctable bits, and
terminating the program operation when the number of error bits is smaller than the number of correctable bits.

11. The method of claim 9, wherein the first number is set based on the number of correctable bits.

12. A non-volatile memory device, comprising:
a page buffer configured to generate a verification result signal in response to a result of programming a plurality of memory cells; and
a result comparator configured to generate a program termination signal by comparing the verification result signal with a reference signal corresponding to a target number of memory cells to be programmed among the plurality of the memory cells.

13. The non-volatile memory device of claim 12, wherein the page buffer comprises:
a confirmation signal input unit configured to receive a programming confirmation signal corresponding to a programming result of each of the plurality of the memory cells and discharge pre-charged charges out of a common node; and
a verification signal output unit configured to output the verification result signal corresponding to a voltage level of the common node in response to a programming confirmation operation.

14. The non-volatile memory device of claim 13, wherein the verification result signal has a pulse width that varies in response to a variation in a number of programmed memory cells among the plurality of the memory cells.

15. The non-volatile memory device of claim 13, further comprising:
a pre-charge unit configured to pre-charge the common node before the programming confirmation operation.

16. The non-volatile memory device of claim 12, wherein the result comparator comprises:
a latch unit configured to latch the verification result signal in response to a latch control signal; and
a comparison unit configured to output the programming termination signal by comparing an output signal of the latch with the reference signal.

17. The non-volatile memory device of claim 16, further comprising:
a plurality of delays configured to generate a plurality of latch control signals as the latch control signal,
wherein the latch unit includes a plurality of latches corresponding to the number of the latch control signals.

18. A method for performing a program operation in a non-volatile memory device, comprising:
applying a programming pulse to a plurality of memory cells;
checking whether the plurality of the memory cells are programmed and outputting a verification signal as a check result;
determining a number of programmed memory cells among the plurality of the memory cells in response to the verification signal to produce a determination result; and
terminating the program operation in response to the determination result.

19. The method of claim 18, wherein the determining of the number of programmed memory cells comprises:
determining whether all of the plurality of the memory cells are programmed in response to the verification signal; and
determining whether a first number of memory cells among the plurality of the memory cells are programmed in response to the determination that less than all of the plurality of the memory cells are programmed.

20. The method of claim 19, wherein, in response to the determination that all of the plurality of the memory cells are programmed, the program operation is terminated.
